(19) United States
(12) Patent Application Publication
(10) Pub. No.: US 2011/0207338 A1
(43) Pub. Date: Aug. 25, 2011

(54) Laser crystallization apparatus and laser crystallization method

(76) Inventors: Young-Jin Chang, Yongin-City (KR); Seong-Hyun Jin, Yongin-City (KR); Jae-Hwan Oh, Yongin-City (KR); Won-Kyu Lee, Yongin-City (KR)

(21) Appl. No.: 12/926,173

(22) Filed: Oct. 29, 2010

(30) Foreign Application Priority Data
Feb. 23, 2010 (KR) 10-2010-0016336

(51) Int. Cl. H01L 21/268; B23K 26/00

(52) U.S. Cl. 438/795; 219/121.78; 257/E21.347

(57) ABSTRACT

A laser crystallization apparatus for crystallizing a thin film of a substrate, the laser crystallization apparatus includes a laser beam emitting unit configured to scan the substrate in a predetermined direction with a laser beam, a stage configured to support the substrate, a fixing part disposed on a first part of the stage, the fixing part having a shape corresponding to a corner of the substrate, and a driving unit configured to lift a second part of the stage to be higher than the first part of the stage, the substrate on the stage being configured to slide toward and engage with the fixing part.

### BACKGROUND

1. Field

Embodiments relate to a laser crystallization apparatus and method. More particularly, embodiments relate to a laser crystallization apparatus and method for easily fabricating a flat panel display having improved image-quality characteristics.

2. Description of the Related Art

Displays may include, e.g., portable, thin flat panel displays. Flat panel displays, e.g., liquid crystal displays or organic light emitting diode displays, may include thin film transistors for driving pixels.

A conventional thin film transistor may include a polysilicon-containing active layer for high-speed operations. The active layer may be formed using polysilicon by forming an amorphous silicon layer on a substrate and crystallizing the amorphous silicon layer with a laser beam.

### SUMMARY

Embodiments are therefore directed to a laser crystallization apparatus and method, which substantially overcome one or more of the problems due to the limitations and disadvantages of the related art.

It is therefore a feature of an embodiment to provide a laser crystallization apparatus configured to fabricate thin film transistors in a flat panel display and improve image quality characteristics therein.

It is therefore another feature of an embodiment to provide a laser crystallization method for easily fabricating a flat panel display having improved image quality characteristics.

At least one of the above and other features and advantages may be realized by providing a laser crystallization apparatus for crystallizing a thin film of a substrate, the laser crystallization apparatus including a laser beam emitting unit configured to scan the substrate in a predetermined direction with a laser beam; a stage configured to support the substrate, a fixing part disposed on a first part of the stage, the fixing part having a shape corresponding to a corner of the substrate, and a driving unit configured to lift a second part of the stage to be higher than the first part of the stage, the substrate on the stage being configured to slide toward and engage with the fixing part.

The fixing part may be positioned at an oblique angle with respect to the predetermined scanning direction, and the substrate may be positioned at the oblique angle with respect to the predetermined scanning direction when engaged with the fixing part.

The fixing part may include first and second sides configured to make contact with the corner of the substrate.

Each of the first side and the second side of the fixing part may be positioned at an oblique angle with respect to the predetermined scanning direction.

The first and second sides may contact each other.

A contact point between the first and second sides may be on an imaginary line connecting a position of the driving unit and a center of the stage.

The first and second sides may be spaced apart from each other.

An intersection point between extension lines of the first and second sides may be on an imaginary line connecting a position of the driving unit and a center of the stage.

The driving unit and the laser beam emitting unit may be arranged on opposite surfaces of the stage and may be configured to reciprocate.

After the substrate is engaged with the fixing part, the driving unit may lower the part of the stage to an original position.

Before the laser beam emitting unit emits a laser beam after the driving unit lowers the part of the stage to the original position, the fixing part may be inserted into the stage.

The substrate or the stage may be movable in the predetermined direction.

At least one of the above and other features and advantages may also be realized by providing a laser crystallization method that is performed using a laser crystallization apparatus including a laser beam emitting unit, a stage, a fixing part disposed on the stage, and a driving unit. The laser crystallization method may include placing a substrate on the stage, lifting a second part of the stage to be higher than the first part of the stage by using the driving unit, such that the substrate on the stage slides toward and engages with the fixing part, the fixing part having a shape corresponding to a corner of the substrate, and scanning the substrate in a predetermined direction with the laser beam emitting unit so as to crystallize the substrate.

Engaging the substrate with the fixing part may include positioning a longitudinal side of the substrate at an oblique angle with respect to the predetermined scanning direction.

Engaging the substrate with the fixing part may include arranging first and second sides of the fixing part to contact a corner of the substrate.

Arranging the first and second sides of the fixing part may include positioning each of the first and second side at an oblique angle with respect to the predetermined scanning direction.

Arranging the first and second sides of the fixing part may include positioning an intersection point between the first and second sides or between extension lines of the first and second sides on an imaginary line connecting a position of the driving unit and a center of the stage.

The driving unit may be disposed on a surface of the stage opposite to the laser beam emitting unit and is configured to reciprocate.

Prior to the scanning of the substrate and after the engaging of the substrate to the fixing part, the laser crystallization method may further include lowering the part of the stage to an original position by using the driving unit.

Before the laser beam emitting unit emits a laser beam and after the driving unit lowers the part of the stage to the original position, the fixing part may be inserted into the stage.

The scanning of the substrate with the laser beam emitting unit may be performed while the substrate or the stage is moved in the predetermined direction.

The predetermined direction may not be perpendicular to or parallel with a lattice pattern of pixels formed after the substrate is crystallized, but the predetermined direction may make an angle with the lattice pattern.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a schematic perspective view of a laser crystallization apparatus according to an embodiment;

FIG. 2 illustrates a schematic perspective view of a substrate engaged with a fixing part in the laser crystallization apparatus of FIG. 1;

FIG. 3 illustrates an enlarged perspective view of the fixing part in FIG. 1;

FIG. 4 illustrates a schematic perspective view of a modification of the fixing part of FIG. 1;

FIGS. 5A through 5F illustrate plan views of a laser crystallization method using the laser crystallization apparatus of FIG. 1; and

FIG. 6 illustrates a plan view of a substrate crystallized by the laser crystallization method explained with respect to FIGS. 5A through 5F.

### DETAILED DESCRIPTION

Korean Patent Application No. 10-2010-0016336, filed on Feb. 23, 2010, in the Korean Intellectual Property Office, and entitled: “Laser Crystallization Apparatus and Laser Crystallization Method,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer (or element) is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

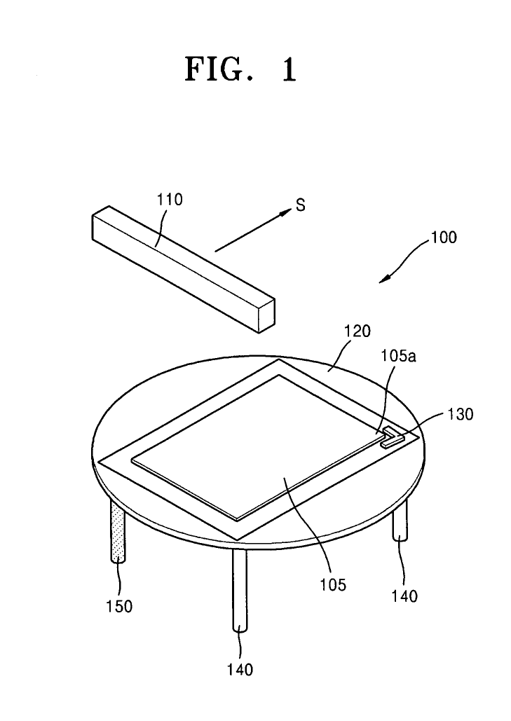

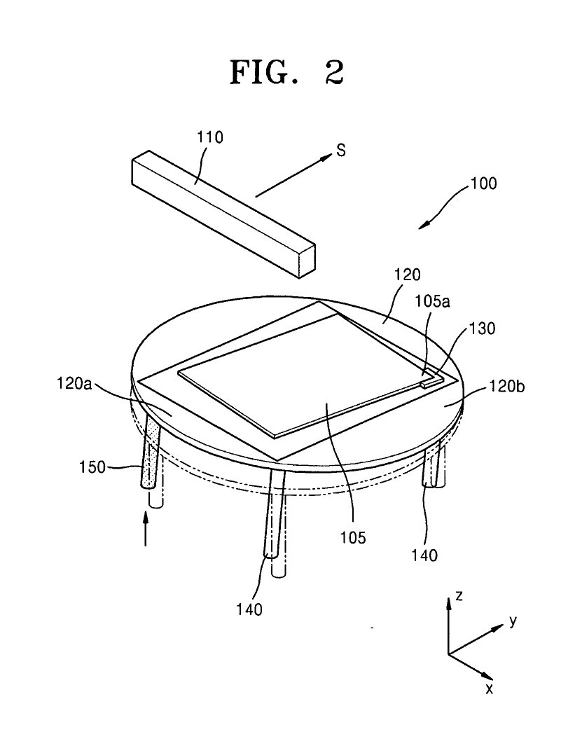

An Embodiment of a laser crystallization apparatus will now be described more fully with reference to FIGS. 1-3. FIG. 1 illustrates a schematic perspective view of a laser crystallization apparatus according to an embodiment, FIG. 2 illustrates a schematic perspective view of a substrate engaged with a fixing part in the laser crystallization apparatus of FIG. 1, and FIG. 3 illustrates an enlarged perspective view of the fixing part according to an embodiment.

Referring to FIGS. 1 and 2, a laser crystallization apparatus 100 may include a laser beam emitting unit 110, a stage 120, a fixing part 130, and a driving unit 150. The laser beam emitting unit 110 emits a laser beam toward the substrate 105 for crystallizing the substrate 105, e.g., crystallizing a layer on the substrate 105.

In detail, the substrate 105 may be used for forming a thin film transistor, e.g., an amorphous silicon layer may be formed on the substrate 105. The substrate 105 may be formed of a transparent material, e.g., glass of which a main component is SiO₂, a transparent plastic, and/or a thin metal film.

The laser beam emitting unit 110 may include a laser source and an optical system to emit a laser beam toward the substrate 105. The laser beam emitting unit 110 may be configured so that the substrate 105 is scanned in a first direction (S), e.g., along the y-axis. That is, the laser beam emitting unit 110 and the substrate 105 may be moved relatively to each other along the first direction (S). For example, the laser beam emitting unit 110 may be moved in the first direction (S), or the stage 120 may be moved in the first direction (S).

The laser beam emitting unit 110 may be suitable for an excimer laser annealing (ELA) apparatus or a sequential lateral solidification (SLS) apparatus. However, the example embodiments are not limited thereto, i.e., the laser beam emitting unit 110 may be applied to various laser-beam crystallization apparatuses.

The substrate 105 may be placed on the stage 120. The stage 120 may be flat, e.g., the stage 120 may include a flat surface supporting the substrate 105, so that the substrate 105 may be firmly placed on the stage 120. A suction part (not shown) may be provided on the surface of the stage 120 for effective contact between the stage 120 and the substrate 105. The stage 120 may further include a plurality of support parts 140 for supporting the stage 120, e.g., the driving unit 150 may function as one of the support parts 140.

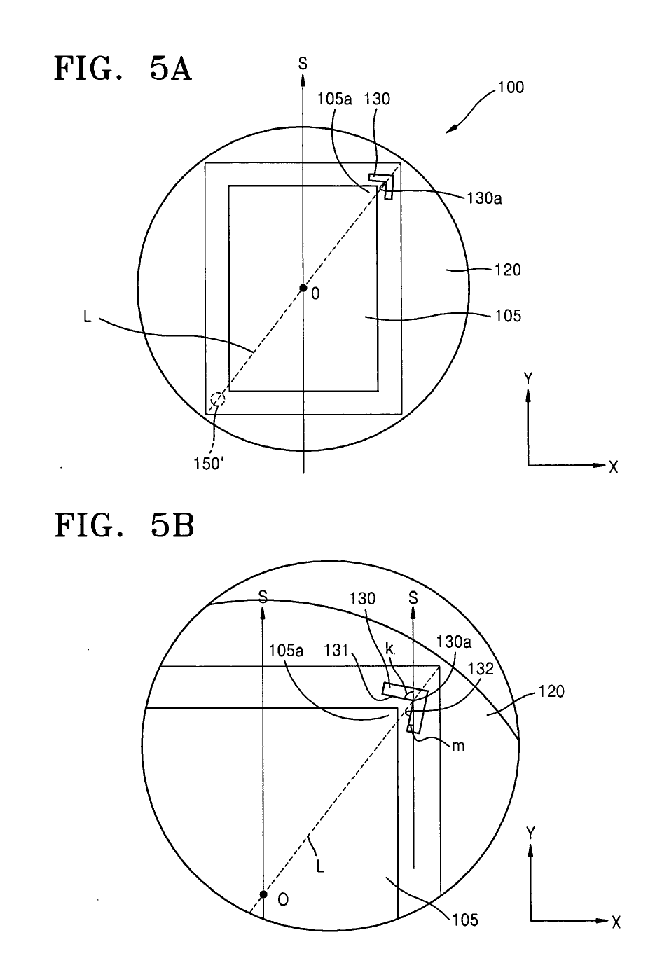

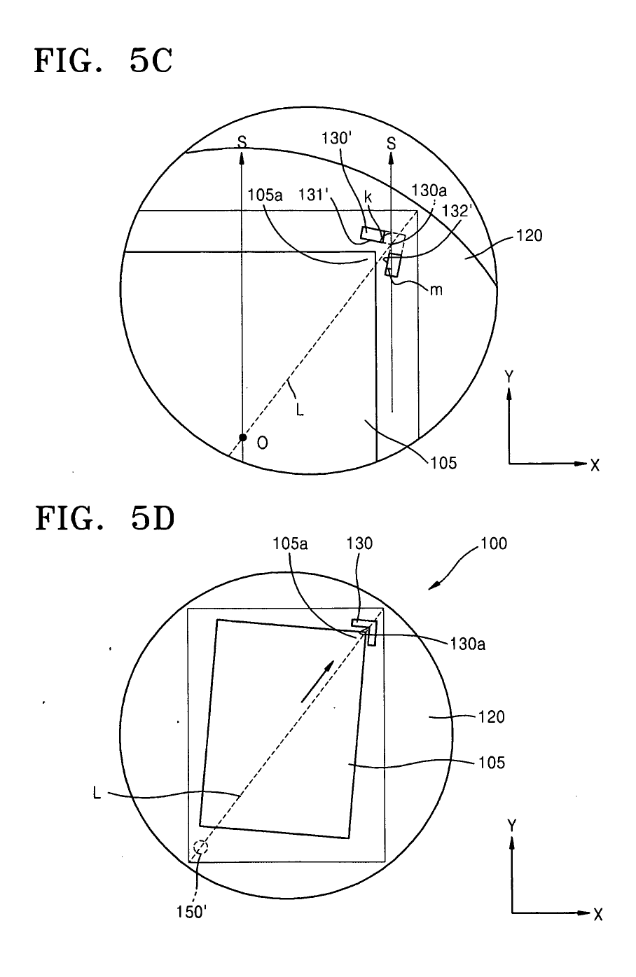

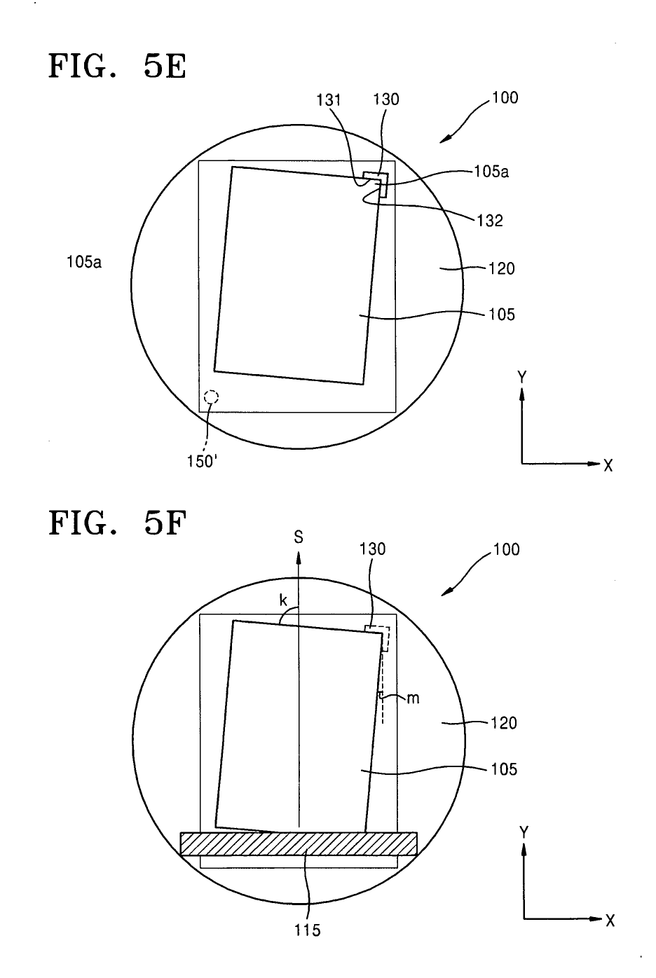

The fixing part 130 may be disposed on, e.g., directly on, the stage 120. The fixing part 130 may have a shape corresponding to a corner 105a of the substrate 105. In detail, as illustrated in FIG. 3, the fixing part 130 may include a first side 131 and a second side 132 arranged to define a shape, e.g., a corner, corresponding to the corner 105a of the substrate 105. That is, the corner 105a of the substrate 105 may be positioned to fit in the corner defined by the first and second sides 131 and 132 of the fixing part 130, e.g., the first and second sides 131 and 132 of the fixing part 130 may be substantially perpendicular to each other. Each of the first and second sides 131 and 132 of the fixing part 130 may be positioned at an oblique angle, e.g., an acute angle, with respect to the first direction (S), as will be discussed in more detail below with reference to FIGS. 5A-5F.

In more detail, the substrate 105 that is placed on the stage 120 may be engaged with the fixing part 130 by an actuation motion of the driving unit 150. Referring to FIG. 2, the corner 105a of the substrate 105 may be tightly engaged with the fixing part 130. As shown in FIG. 3, after the substrate 105 is engaged with the fixing part 130, the vertex of the corner 105a of the substrate 105 may be placed at a point 130a at which the first side 131 and the second side 132 meet each other. It is noted that the point 130a refers to an inner point of the fixing part 130 that faces the substrate 105, i.e., an intersection point of inner edges of the first and second sides 131 and 132 that face the substrate 105.

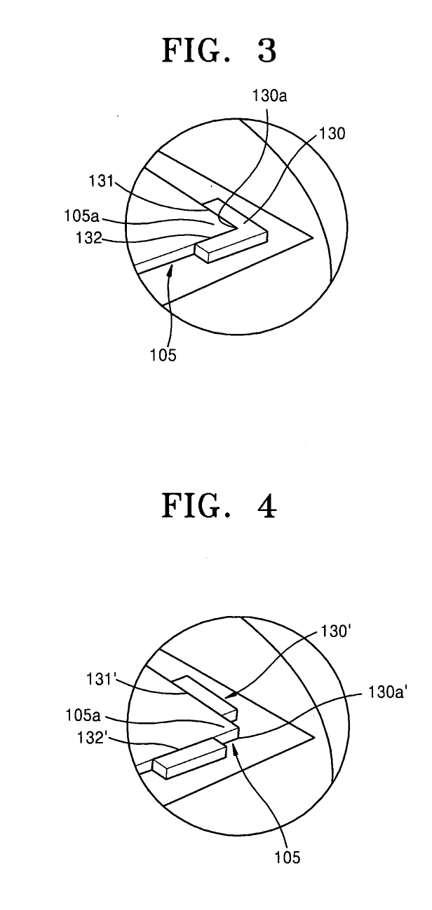

It is noted that while FIG. 3 illustrates that the first side 131 and the second side 132 of the fixing part 130 contact each other at point 130a, embodiments are not limited thereto. For example, as illustrated in FIG. 4, a fixing part 130′ may include a first side 131′ and a second side 132′ that are spaced apart from each other, i.e., may not contact each other. In this case, after the substrate 105 is engaged with the fixing part 130′, the vertex of the corner 105a of the substrate 105 may be placed at a point 130a′, i.e., an intersection point of imaginary extension lines of the first and second sides 131′ and 132′. A more detailed structure of the fixing part 130 (or fixing part 130′) will be described later when a crystallization method is explained with reference to FIGS. 5A-5F.

As illustrated in FIG. 1, the driving unit 150 may be disposed at a bottom side of the stage 120, e.g., the driving unit 150 and the fixing part 130 may be positioned to correspond to, e.g., adjacent to, respective diagonally arranged parts of the stage 120. The driving unit 150 may be operable, e.g., movable, along a vertical direction, e.g., along the z-axis. That is, as illustrated in FIG. 2, when the substrate 105 is placed on the stage 120, the driving unit 150 may operate along the z-axis in an upward direction, i.e., in a direction opposite a direction of gravity, to lift, e.g., only, a first part 120a, e.g., a part including one corner of the substrate 105, of the stage 120. As a result, the stage 120 may be tilted at an oblique angle with respect to a surface supporting the stage 120, so the first part 120a of the stage 120 adjacent to the driving unit 150 may be positioned at a higher level than a second part 120b of the stage 120, e.g., a part including the corner 105a of the substrate 105 and arranged diagonally with respect to the first part 120a, adjacent to the fixing part 130.

Since the driving unit 150 tilts the stage 120 to have the fixing part 130 at a lower position relative to the diagonally arranged first part 120a of the stage 120, the substrate 105 may slide, e.g., smoothly move, toward the fixing part 130 by gravity. Then, the substrate 105 may be stopped by the fixing part 130. That is, the substrate 105 may be engaged with the fixing part 130, so the corner 105a of the substrate 105 fits between the first and second sides 131 and 132 of the fixing part 130. This operation will be described later in more detail.

After the substrate 105 is engaged with the fixing part 130, the driving unit 150 may move downward along the z-axis, i.e., in a direction of gravity, so that the stage 120 may return to its original position, i.e., a horizontal position substantially in parallel with the surface supporting the stage 120. Thereafter, the substrate 105 may be crystallized using the laser beam emitting unit 110. At this time, the fixing part 130 may be retracted into the stage 120. Since the stage 120 on which the substrate 105 is placed is tilted, the substrate 105 may define a predetermined angle with the firs direction (S) (scanning direction), as will be described later.

FIGS. 5A through 5F illustrate plan views in a laser crystallization method using the laser crystallization apparatus 100 according to an embodiment. Referring to FIG. 5A, the substrate 105 may be placed on the stage 120. FIG. 5B illustrates an enlarged plan view of the fixing part 130 in FIG. 5A, and FIG. 5C illustrates an enlarged plan view of the fixing part 130′ on the stage 120. It is noted that in FIGS. 5A through 5C, (S) denotes a scanning direction of a laser beam, i.e., along the y-axis.

Referring to FIG. 5A, the corner 105a of the substrate 105 may be placed close to the fixing part 130. In FIG. 5A, while the driving unit 150 is not illustrated, the position of the driving unit 150 is indicated by reference numeral 150′. A point (O) denotes a center of the stage 120. The point 130a of the first side 131 and the second side 132 of the fixing part 130 is located on a line (L) connecting the driving unit position 150′ and the point (O).

As discussed previously, the fixing part may be positioned at a predetermined angle with respect to the first direction (S), so each of the first and second sides 131 and 132 of the fixing part 130 may be positioned at an oblique angle with respect to the first direction (S). In detail, as illustrated in FIGS. 5A and 5B, the first side 131 of the fixing part 130 is not perpendicular to the first direction (S) of the laser beam emitting unit 110, i.e., the first side 131 may define an oblique angle (k) with the first direction (S). Similarly, the second side 132 of the fixing part 130 is not parallel with the first direction (S), i.e., the second side 132 may define an oblique angle (m) with the first direction (S). Therefore, after the corner 105a of the substrate 105 is engaged with the fixing part 130, the length or width direction of the substrate 105 may not be parallel with or perpendicular to the first direction (S), respectively, but may define angles (m) and (k) with the first direction (S), respectively.

It is noted that the substrate 105 in the modified embodiment of FIG. 4 may be positioned in the fixing part 130′, as described previously with reference to FIGS. 5A and 5B. That is, referring to FIG. 5C, the first side 131′ and the second side 132′ of the fixing part 130′ may be spaced apart from each other. The point 130a′ at which imaginary extension lines of the first and second sides 131′ and 132′ meet each other may be placed on the line (L). The first side 131′ of the fixing part 130 is not perpendicular to the first direction (S) of the laser beam emitting unit 110 but makes an angle (k) with the first direction (S). The second side 132 of the fixing part 130 is not parallel with the scanning direction (S) but makes an angle (m) with the first direction (S).

Referring to FIG. 5D, once the substrate 105 is placed on the stage 120 adjacent to the fixing part 130, the driving unit 150 disposed at the point 150′ may be operated to lift the first part 120a of the stage 120, so that the second part 120b of the stage 120, e.g., a corner, where the fixing part 130 is disposed may be at a lower level relatively to the lifted part of the stage 120. As a result, the stage 120 is tilted, and the substrate 105 placed on the stage 120 may slide, i.e., may smoothly move, toward the fixing part 130 by gravity. In FIG. 5D, the moving direction of the substrate 105 is indicated by an arrow, i.e., along the line (L).

Referring to FIG. 5E, the substrate 105 may be engaged with the fixing part 130. In detail, the corner 105a of the substrate 105 may be brought into contact with the first and second sides 131 and 132 of the fixing part 130. In this state where the substrate 105 is engaged with the fixing part 130, although not shown in FIG. 5E, the stage 120 may be returned to its original position. That is, after the substrate 105 is engaged with the fixing part 130, the lifted part of the stage 120 may be lowered by the driving unit 150 to make the stage 120 horizontal. In this state, the substrate 105 engaged with the fixing part 130 may not be moved.

Referring to FIG. 5F, the substrate 105 may be crystallized by scanning the substrate 105 in the first direction (S) with a laser beam 115. During the scanning, the substrate 105 is not parallel with or perpendicular to the first direction (S), i.e., the scanning direction, but the width direction of the substrate 105 may define an oblique angle (k) with the first direction (S) and the length direction of the substrate 105, i.e., a longitudinal side of the substrate 105 extending perpendicularly to the width direction, may define an oblique angle (m) with the first direction (S). That is, the substrate 105 may define same angles with the first direction (S) as the angles between the first direction (S) and each of the first and second sides 131 and 132, respectively.

The laser beam 115 is a line beam emitted from the laser beam emitting unit 110 illustrated in FIG. 1. In FIG. 5F, the width of the laser beam 115 along the x-axis is larger than the width of the substrate 105. However, example embodiments are not limited thereto, e.g., the laser beam 115 may have a smaller width than the width shown in FIG. 5F. In this case, the substrate 105 may be crystallized by scanning the substrate 105 a plurality of times with the laser beam 115.

In FIG. 5F, the fixing part 130 is indicated by dashed lines to denote that the fixing part 130 may be retracted into the stage 120 before a crystallization process is performed. That is, after the substrate 105 is engaged with the fixing part 130 to make an oblique angle with the first direction (S) and is secured to the stage 120, the fixing part 130 may be retracted to avoid exposure to the laser beam 115.

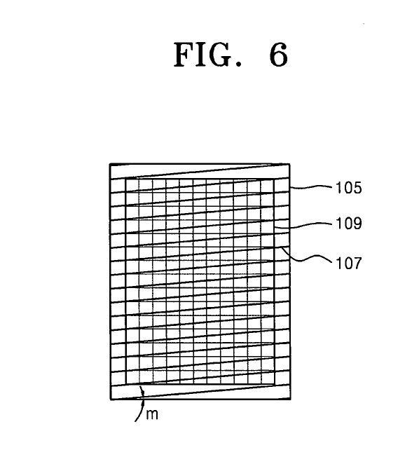

FIG. 6 illustrates a plan view of the substrate 105 after crystallization by the laser crystallization method explained with respect to FIGS. 5A through 5F.

During crystallization of the substrate 105 with the laser crystallization apparatus 100 according to example embodiments, a beam pattern 107 may be formed on the substrate 105, i.e., when the substrate 105 is scanned with the laser beam 115. After the substrate 105 is crystallized, a plurality of thin film forming processes may be performed on the substrate 105 to form a plurality of pixels on the substrate 105. The pixels may form a lattice pattern 109 on the substrate 105. As illustrated in FIG. 6, the beam pattern 107 and the lattice pattern 109 are not parallel with or perpendicular to each other but cross each other at an angle (m).

In contrast, during a conventional crystallization method, e.g., when a substrate is positioned in parallel to the scanning direction, a laser beam pattern may remain on the substrate along a trace of the beam in parallel with or perpendicular to a lattice pattern formed by pixels, e.g., the laser beam pattern may be repeatedly superimposed on a lattice pattern formed by gate and data lines that cross each other to form pixels or in parallel with the lattice pattern of the pixels. As such, a moire pattern may be generated, thereby deteriorating an image quality of a display device.

However, since the beam pattern 107 in the example embodiments crosses the lattice pattern 109 at an angle (m), generation of moire patterns may be effectively prevented. Therefore, as described above, according to the laser crystallization apparatus and method of the example embodiments, a flat panel display having improved image-quality characteristics may be easily fabricated.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A laser crystallization apparatus for crystallizing a thin film of a substrate, the laser crystallization apparatus comprising:
a laser beam emitting unit configured to scan the substrate in a predetermined direction with a laser beam;
a stage configured to support the substrate;
a fixing part disposed on a first part of the stage, the fixing part having a shape corresponding to a corner of the substrate; and
a driving unit configured to lift a second part of the stage to be higher than the first part of the stage, the substrate on the stage being configured to slide toward and engage with the fixing part.

2. The laser crystallization apparatus as claimed in claim 1, wherein the fixing part is positioned at an oblique angle with respect to the predetermined scanning direction, and the substrate is positioned at the oblique angle with respect to the predetermined scanning direction when engaged with the fixing part.

3. The laser crystallization apparatus as claimed in claim 1, wherein the fixing part includes first and second sides, the first and second sides being arranged to contact a corner of the substrate.

4. The laser crystallization apparatus as claimed in claim 3, wherein each of the first side and the second side of the fixing part is positioned at an oblique angle with respect to the predetermined scanning direction.

5. The laser crystallization apparatus as claimed in claim 3, wherein the first and second sides contact each other.

6. The laser crystallization apparatus as claimed in claim 5, wherein a contact point between the first and second sides is on an imaginary line connecting a position of the driving unit and a center of the stage.

7. The laser crystallization apparatus as claimed in claim 3, wherein the first and second sides are spaced apart from each other.

8. The laser crystallization apparatus as claimed in claim 7, wherein an intersection point between extension lines of the first and second sides is on an imaginary line connecting a position of the driving unit and a center of the stage.

9. The laser crystallization apparatus as claimed in claim 1, wherein the driving unit and the laser beam emitting unit are arranged on opposite surfaces of the stage and are configured to reciprocate.

10. The laser crystallization apparatus as claimed in claim 1, wherein the fixing part is configured to retract into the stage before the laser beam scanning.

11. The laser crystallization apparatus as claimed in claim 1, wherein the substrate and/or the stage are movable in the predetermined direction.

12. The laser crystallization apparatus as claimed in claim 1, further comprising a plurality of support parts configured to support the stage.

13. The laser crystallization apparatus as claimed in claim 12, wherein the driving unit also functions as one of the support parts.

14. A laser crystallization method using a laser crystallization apparatus including a laser beam emitting unit, a stage, a fixing part disposed on a first part of the stage, and a driving unit, the laser crystallization method comprising:
placing a substrate on the stage;
lifting a second part of the stage to be higher than the first part of the stage by using the driving unit, such that the substrate on the stage slides toward and engages with the fixing part, the fixing part having a shape corresponding to a corner of the substrate; and
scanning the substrate in a predetermined direction with the laser beam emitting unit so as to crystallize the substrate.

15. The laser crystallization method as claimed in claim 14, wherein engaging the substrate with the fixing part includes positioning a longitudinal side of the substrate at an oblique angle with respect to the predetermined scanning direction.

16. The laser crystallization method as claimed in claim 14, wherein engaging the substrate with the fixing part includes arranging first and second sides of the fixing part to contact a corner of the substrate.

17. The laser crystallization method as claimed in claim 16, wherein arranging the first and second sides of the fixing part includes positioning each of the first and second side at an oblique angle with respect to the predetermined scanning direction.

18. The laser crystallization method as claimed in claim 16, wherein arranging the first and second sides of the fixing part includes positioning an intersection point between the first and second sides or between extension lines of the first and second sides on an imaginary line connecting a position of the driving unit and a center of the stage.

19. The laser crystallization method as claimed in claim 14, wherein prior to scanning of the substrate and after engaging the substrate with the fixing part, the laser crystallization method further comprises lowering the second part of the stage, such that the substrate is substantially horizontal during scanning.

20. The laser crystallization method as claimed in claim 19, wherein before the laser beam emitting unit emits a laser beam and after the driving unit lowers the second part of the stage, the fixing part is inserted into the stage.

21. The laser crystallization method as claimed in claim 14, wherein the scanning of the substrate with the laser beam emitting unit is performed while the substrate or the stage is moved in the predetermined direction.

22. The laser crystallization method as claimed in claim 14, wherein the predetermined scanning direction is at an oblique angle with respect to a lattice pattern of pixels formed after the substrate is crystallized.
